(19) United States
(12) Patent Application Publication
(10) Pub. No.: US 2012/0256162 A1
(43) Pub. Date: Oct. 11, 2012

(54) LIGHT EMITTING DIODE AND MANUFACTURING METHOD THEREOF

(75) Inventors: Chia-Hung HUANG, Hsinchu (TW); Po-Min TU, Hsinchu (TW); Shih-Cheng HUANG, Hsinchu (TW); Shun-Kuei YANG, Hsinchu (TW)

(73) Assignee: ADVANCED OPTOELECTRONIC TECHNOLOGY, INC., Hsinchu Hsien (TW)

(21) Appl. No.: 13/437,937

(22) Filed: Apr. 3, 2012

(30) Foreign Application Priority Data
Apr. 8, 2011 (CN) 201110087736.3

(51) Int. Cl. H01L 33/06

(52) U.S. Cl. 257/13; 438/47; 257/E33.008

(57) ABSTRACT

A light emitting diode includes a substrate, an N-type semiconductor layer arranged on the substrate, an active layer, and a P-type semiconductor layer. The active layer includes a first barrier layer, a second barrier layer, and a quantum well structure layer arranged between the first and second barrier layers. The quantum well structure layer includes an InN layer, a GaN layer and an InGaN layer arranged on the first barrier layer in sequence. The InN layer has an upper surface connected to the GaN layer. The upper surface is rough. The InGaN layer has a concentration of In atoms in some regions of the InGaN layer which is higher that that in other regions thereof. The P-type semiconductor layer is arranged on the second barrier layer.

### BACKGROUND

1. Technical Field

The present disclosure generally relates to solid state light emitting devices and, more particularly, to a light emitting diode (LED) with high light extraction efficiency and manufacturing method thereof.

2. Description of the Related Art

LEDs have many advantages, such as high luminosity, low operational voltage, low power consumption, compatibility with integrated circuits, easy driving, long term reliability, and environmental friendliness, which have promoted the wide use of LEDs as a light source.

Generally, an LED includes a substrate, an N-type semiconductor contact layer, an active layer and a P-type semiconductor contact layer arranged on the substrate in sequence. Part of light emitted from the active layer transmits to the substrate and is absorbed by the substrate; therefore, the light extraction efficiency of the LED is not high.

Therefore, what is needed is an LED and manufacturing method thereof which can overcome the described limitations.

### BRIEF DESCRIPTION OF THE DRAWINGS

FIG. 1 is a cross-sectional view of an LED, according to an exemplary embodiment of the present disclosure.

FIG. 2 is a partially enlarged view showing atom distribution of an InGaN layer of the LED of FIG. 1.

FIGS. 3-7 are cross-sectional views showing different steps of an embodiment of a method for manufacturing the LED of FIG. 1.

### DETAILED DESCRIPTION OF EMBODIMENTS

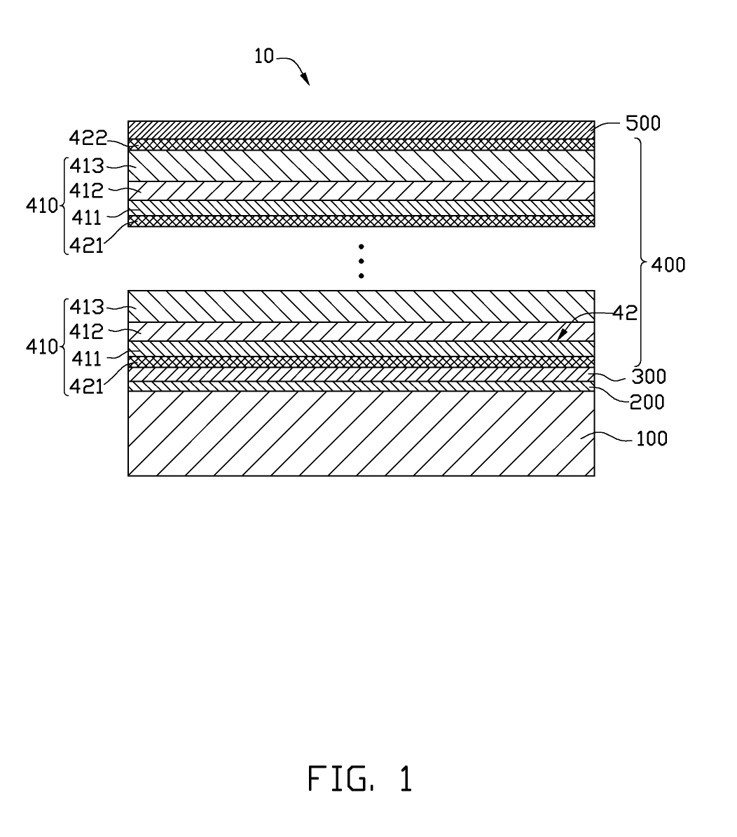

Referring to FIG. 1, an LED 10, in accordance with an embodiment, is provided. The LED 10 includes a substrate 100, and a buffer layer 200, an N-type semiconductor layer 300, an active layer 400, and a P-type semiconductor layer 500 arranged on the substrate 100 in sequence.

The substrate 100 preferably is a monocrystal plate and can be made of a material of sapphire, silicon carbide (SiC), silicon (Si), gallium arsenide (GaAs), lithium aluminate (LiAlO₂), magnesium oxide (MgO), zinc oxide (ZnO), GaN, aluminum nitride (AlN) or indium nitride (InN), etc. In the present embodiment, the substrate 10 is made of sapphire.

The buffer layer 200 is formed on an upper surface of the substrate 100. In the present embodiment, the buffer layer 200 is a nitride semiconductor layer.

The N-type semiconductor layer 300 is grown on the buffer layer 200 by epitaxy. The buffer layer 20 reduces the lattice mismatch between the substrate 100 and the grown N-type semiconductor layer 300.

The active layer 400 includes multiple quantum well structure layers 410 stacked in the N-type semiconductor layer 300, and a barrier layer 422 arranged on the quantum well structure layers 410. Each quantum well structure layer 410 includes a first barrier layer 421, an InN layer 411, a GaN layer 412, and an InGaN layer 413 arranged along a direction away from the N-type semiconductor layer 300 in sequence. In the present embodiment, the InN layer 411 has an upper surface 42 connected to the GaN layer 412. The upper surface 42 of the InN layer 411 is rough, and the GaN layer 412 protects the upper surface 42 of the InN layer 411. In the present embodiment, the first barrier layer 421 and the barrier layer 422 are GaN layers.

In the present embodiment, after forming the InN layer 411 on the first barrier layer 421, hydrogen or ammonia is introduced to the InN layer 411 and heated. The introduced time to the InN layer 411 and heated temperature of the hydrogen or ammonia are so controlled that the chemical bonds in the upper surface 42 of the InN layer 411 are destroyed; therefore, the upper surface 42 of the InN layer 411 is rough since the chemical bonds in the upper surface 42 of the InN layer 411 are destroyed. Generally, the introduced time and the heated temperature of the hydrogen or ammonia are dependent on a thickness of the InN layer 411. For example, if the thickness of the InN layer 411 is 0.002 microns, the introduced time of the hydrogen or ammonia is about 12 seconds, and the heated temperature is about 550 degrees Celsius. In the present embodiment, the upper surface 42 of every InN layer 411 is roughened.

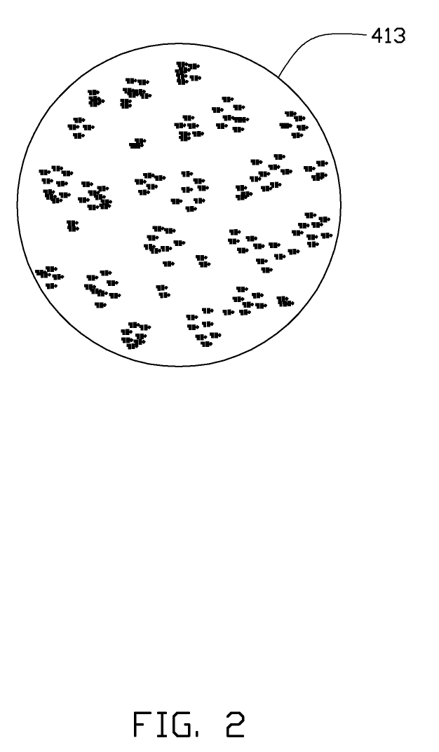

Also referring to FIG. 2, in the present embodiment, the lattice of the InGaN layer 413 matches with that of the InN layer 411; therefore, the distribution of the In atom of the InGaN layer 413 is not uniform since the upper surface 42 of the InN layer 411 is rough. The light extraction efficiency of the LED 10 is improved since the concentration of In atoms in some regions of the InGaN layer 413 is higher that that in other regions thereof.

The P-type semiconductor layer 500 is formed on the barrier layer 422. In the present embodiment, the amount of the quantum well structure layers 410 can be ranged from one to twenty.

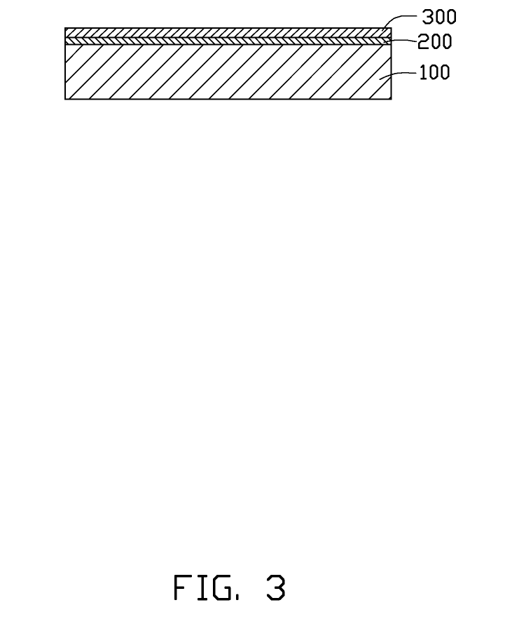

Referring to FIGS. 3-7, a method for manufacturing the LED 10 in accordance with an exemplary embodiment is also disclosed, and includes:

Step 1: referring to FIG. 3, providing a substrate 100, forming a buffer layer 200 on the substrate 100, and forming an N-type semiconductor layer 300 on the buffer layer 200. In the present embodiment, the substrate 10 is made of sapphire.

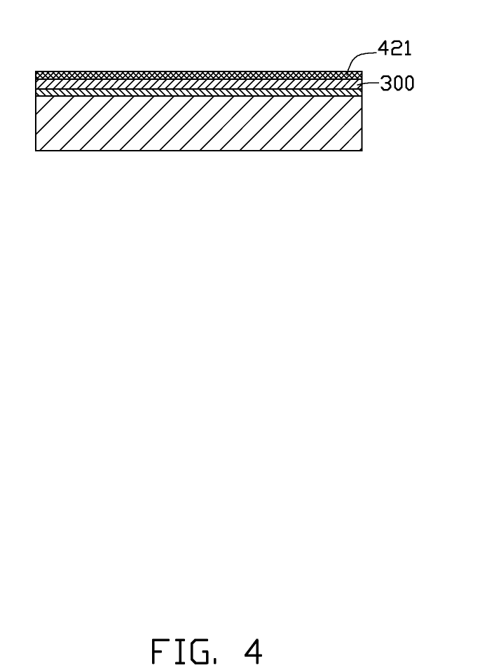

Step 2: referring to FIG. 4, forming a first barrier layer 421 on the N-type semiconductor layer 300. In the present embodiment, the first barrier layer 421 is a GaN layer.

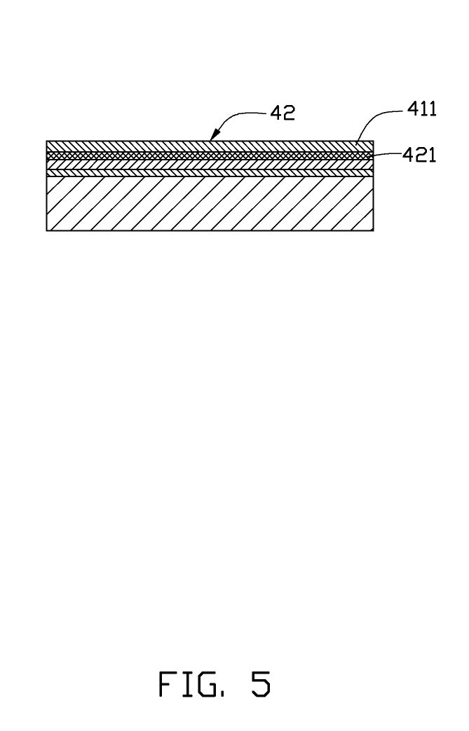

Step 3: referring to FIG. 5, forming an InN layer 411 on the first barrier layer 421, and introducing heated hydrogen or ammonia to the InN layer 411. The chemical bonds in an upper surface 42 of the InN layer 411 are destroyed via an action of the heated hydrogen or ammonia; therefore, the upper surface 42 of the InN layer 411 is roughened.

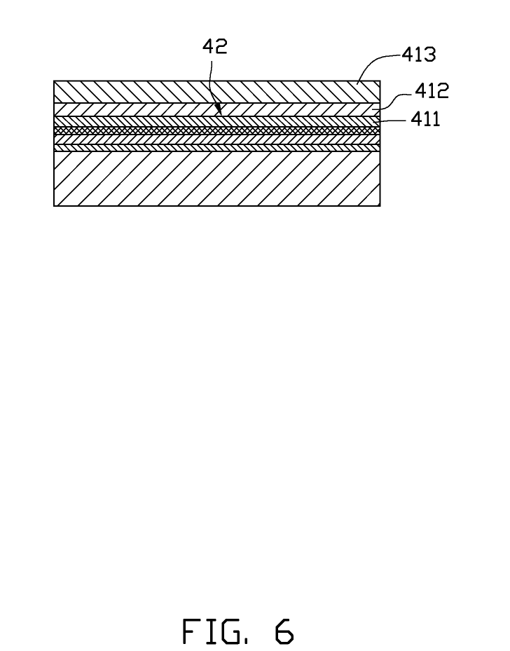

Step 4: referring to FIG. 6, forming a GaN layer 412 on the upper surface 42 of the InN layer 411, and an InGaN layer 413 on the GaN layer 412. The InN layer 411, the GaN layer 412 and the InGaN layer 413 cooperatively construct a quantum well structure layer 410.

Step 5: repeating the step 2 and step 4 to form multiple quantum well structure layers 410 on the N-type semiconductor layer 300.

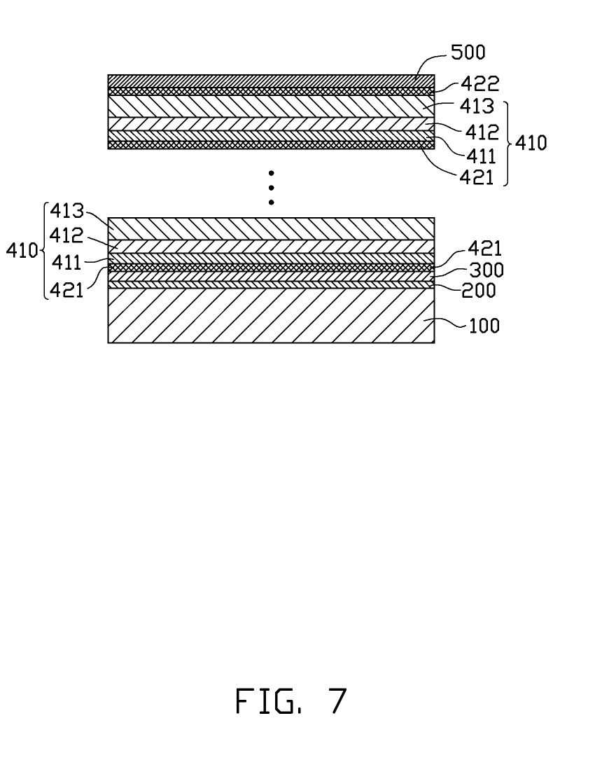

Step 6: referring to FIG. 7, forming a second barrier layer 422 on the multiple quantum well structure layers 410, and a P-type semiconductor layer 500 on the second barrier layer 422. Thus, the LED 10 is obtained. In the present embodiment, the second barrier layer 422 is a GaN layer.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) comprising:
a substrate;
an N-type semiconductor layer arranged on the substrate;
an active layer comprising at least a quantum well structure layer arranged on the N-type semiconductor layer and a barrier layer arranged on the quantum well structure layer, the at least a quantum well structure layer comprising at least a first barrier layer, at least an InN layer and an InGaN layer arranged on the N-type semiconductor layer in sequence, the at least an InN layer having an upper surface which is rough and the at least an InGaN layer having a concentration of In atoms in some regions of the at least an InGaN layer which is higher that that in other regions thereof; and
a P-type semiconductor layer arranged on the barrier layer.

2. The LED of claim 1, further comprising a buffer layer arranged between the substrate and the N-type semiconductor layer.

3. The LED of claim 1, wherein the at least a quantum well structure layer further comprises at least a GaN layer arranged between the at least an InN layer and the at least an InGaN layer.

4. An LED comprising:
a substrate;
an N-type semiconductor layer arranged on the substrate;
an active layer comprising a multiple quantum well structure layer arranged on the N-type semiconductor layer and a barrier layer arranged on the multiple quantum well structure layer, each quantum well structure layer comprising a first barrier layer, an InN layer, a GaN layer and an InGaN layer arranged on the N-type semiconductor layer in sequence, the InN layer having an upper surface adjacent to the GaN layer, the upper surface being rough, the InGaN layer having a concentration of In atoms in some regions of the InGaN layer which is higher that that in other regions thereof;
a P-type semiconductor layer arranged on the barrier layer.

5. The LED of claim 4, further comprising a buffer layer arranged between the substrate and the N-type semiconductor layer.

6. A method for manufacturing the LED, comprising:
Step 1: providing a substrate;
Step 2: forming an N-type semiconductor layer arranged on the substrate;
Step 3: forming a first barrier layer on the N-type semiconductor layer;
Step 4: forming an InN layer on the first barrier layer, and introducing heated hydrogen or ammonia to the InN layer to roughen an upper surface of the InN layer;
Step 5: forming an InGaN layer over the InN layer;
Step 6: forming a second barrier layer on the InGaN layer, and then forming a P-type semiconductor layer on the second barrier layer, wherein the InGaN layer has a concentration of In atoms in some regions of the InGaN layer which is higher that that in other regions thereof.

7. The method of claim 6 further comprising forming a buffer layer on the substrate before step 2.

8. The method of claim 6 further comprising forming a GaN layer on the upper surface of the InN layer before step 5 and in step 5 the InGaN layer is formed on the GaN layer.

9. The method of claim 6, wherein the InN layer and the InGaN layer cooperatively define a quantum well structure layer, and before step 6, steps 3, 4 and 5 are repeated until a required amount of the quantum well structure layer is obtained.
